(19) United States
(12) Patent Application Publication
(10) Pub. No.: US 2011/0147587 A1
(43) Pub. Date: Jun. 23, 2011

(54) DIAGNOSIS DEVICE OF RECIPE USED FOR SCANNING ELECTRON MICROSCOPE

(76) Inventors: Kyoungmo Yang, Mito (JP); Junichi Kakuta, Hitachinaka (JP); Yukari Yamada (nee Nakata), Naka (JP)

(21) Appl. No.: 13/059,667

(22) PCT Filed: Sep. 16, 2009
(86) PCT No.: PCT/JP2009/004620

§ 371 Date: Feb. 18, 2011

(30) Foreign Application Priority Data
Sep. 30, 2008 (JP) 2008-252151

(51) Int. Cl. H01J 37/285

(52) U.S. Cl. 250/310

(57) ABSTRACT

Disclosed is a diagnosis device of a recipe used for a scanning electron microscope that quickly specifies an error causing factor of the recipe due to a process fluctuation or the like. Specifically disclosed is, a diagnosis device of a recipe to operate a scanning electron microscope is provided with a program to make a display device show shift in a score indicating the degree of pattern matching consistency, wherein a condition of the pattern matching is set in the recipe; a deviation of coordinates before and after the pattern matching; changes in information or the like on fluctuation amounts of a lens before and after the execution of automatic focuses.

### TECHNICAL FIELD

The present invention relates to a diagnosis method and program of a recipe for setting the operating conditions for a device such as a scanning electron microscope. More particularly, it relates to a diagnosis method and device for executing the recipe diagnosis based on information acquirable at the time of the recipe execution.

### BACKGROUND ART

In a scanning electron microscope used for the measurement or inspection of a semiconductor device, the measurement or inspection is executed based on a program which is referred to as “recipe”. Here, the measurement conditions associated are registered into this recipe. If the recipe of the scanning electron microscope like this is not set correctly, this incorrect setting of the recipe becomes a cause for the occurrence of an error. Then, this error occurrence becomes a factor of obstructing the automation of the device. In Patent Literature 1, as a method for automatically creating the recipe like this, there is disclosed a technology for automatically creating the recipe based on the design data of the semiconductor device.

### CITATION LIST

### Patent Literature

[Patent Literature 1]: JP-A-2008-147143

### SUMMARY OF INVENTION

### Technical Problem

Of scanning electron microscopes, a device for making the measurement or inspection of mass-produced semiconductor devices is used for measuring the large number of mass-produced samples in a fixed-point observation manner and checking the resultant finished quality of the samples. Accordingly, operations such as the measurement based on the same recipe are continuously performed.

Even in the samples fabricated by the same mass-production steps, however, because of a cause such as a variation in the semiconductor processes, for example, a pattern to be used for the addressing is found to change in comparison with the initial pattern. Consequently, there occurs a necessity for performing a task of swiftly identifying an error-occurrence factor like this, and optimizing the recipe. It is difficult, however, to predict the process variation and to update the recipe with appropriate timing. Once the error has occurred, the device halts. Accordingly, it becomes impossible to perform the operations such as the measurement during this halting time-interval. Consequently, there is a necessity for identifying the error-occurrence factor and optimizing the recipe with appropriate timing before the very error occurs. In the recipe-creating method disclosed in Patent Literature 1, however, the recipe is created based on the design data which indicates an ideal shape and the unpredictable process variation can not have been sufficiently addressed.

Hereinafter, the explanation will be given below concerning a device of diagnosing a recipe used for a scanning electron microscope. Here, an object of the recipe diagnosis device is the swift identification of the factor for an error occurrence in the recipe due to such a cause as the process variation.

### Solution to Problem

As an aspect for accomplishing the above-described object, a device of diagnosing a recipe used for operating a scanning electron microscope is proposed, including a program for allowing the transition of information to be displayed on a display device, the information being about a score for indicating the degree of agreement of pattern matching, a coordinate shift before and after the pattern matching, or an amount of variation of a lens before and after autofocus of the lens, for all of which conditions are set in the recipe.

### Advantageous Effects of Invention

According to the above-described configuration, it becomes possible to grasp the transition of a change in the information acquired by the scanning electron microscope operated by the execution of the recipe. Accordingly, it becomes possible for a recipe-setting person to grasp the situation of the change, and, based on this grasp of the situation, to make an adjustment of the recipe with appropriate timing. As a result of this adjustment, it further becomes possible to maintain the automation ratio of the scanning electron microscope up into a high state.

### BRIEF DESCRIPTION OF DRAWINGS

FIG. 1 A diagram for explaining the overview of a scanning electron microscope (SEM).

FIG. 2 A diagram for explaining an embodiment of a control device connected to the SEM.

FIG. 3 A diagram for explaining an embodiment of the display mode for visually checking the past history of the SEM.

FIG. 4 A diagram for explaining an embodiment of the display mode of shift information about a critical-dimension measurement target.

FIG. 5 A diagram for explaining an embodiment of the diagnosis step of diagnosing a recipe portion to which global alignment conditions using an optical microscope are set.

FIG. 6 A diagram for explaining an embodiment of the step of diagnosing a recipe portion in which global alignment conditions using the SEM are set.

FIG. 7 A diagram for explaining an embodiment of the step of diagnosing a recipe portion in which addressing conditions using the SEM are set.

FIG. 8 A diagram for explaining an embodiment of the step of diagnosing a recipe portion in which measurement conditions in the critical-dimension measurement object are set.

FIG. 9 A diagram for explaining an embodiment of a screen for setting measurement conditions with the CD-SEM.

FIG. 10 A diagram for explaining an embodiment of a selection screen for selecting the operation history of the device acquired in the CD-SEM.

### DESCRIPTION OF EMBODIMENTS

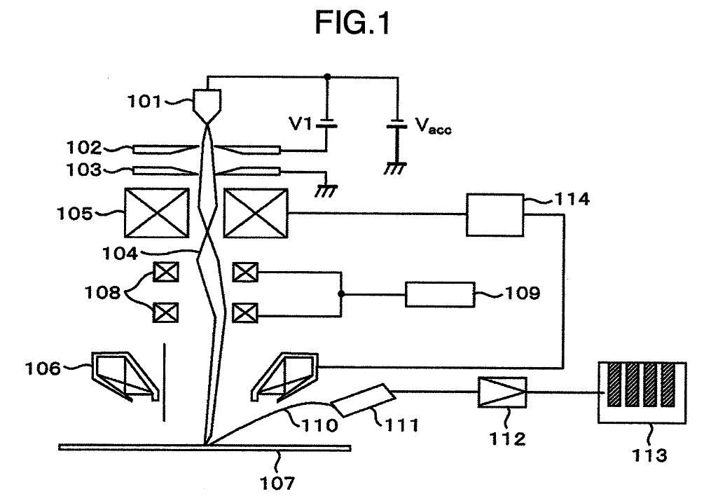

FIG. 1 is a diagram for explaining the overview of a scanning electron microscope (Scanning Electron Microscope: SEM). An electron beam 104 is emitted from a cathode 101, then being extracted by the application of a voltage V1 to a first anode 102. Next, the electron beam 104 is accelerated by a second anode 103 to which an acceleration voltage Vacc is applied, thereby proceeding to a subsequent-stage lens system. Moreover, the electron beam 104 is converged onto a wafer 107 by a condenser lens 105 and an objective lens 106, both of which are controlled by a lens control power-supply 114. Incidentally, in the present embodiment, magnetic-field-type lenses are used which converge an electron beam using a magnetic field. The present embodiment, however, is not limited thereto. Instead, the so-called electrostatic-type lenses may also be used which converge an electron beam using an electric field.

The electron beam 104 is scanned on the surface of the sample in a one-dimensional or two-dimensional manner by a deflector (a deflection coil 108 in the case of the present embodiment) which deflects an electron beam with the effect of an electric field or magnetic field thereto. The deflection coil 108, which is connected to a deflector control power-supply 109, receives the supply of a current needed for implementing the deflection. Secondary electrons (Secondary Electron: SE) and backscattered electrons (Backscattered Electron: BSE), which are emitted from the sample based on the electron-beam scanning, are detected by an electron detector 111.

The electrons detected by the electron detector 111 are amplified by an amplifier 112, then being supplied as a luminance signal of the display device 113, to which a deflection signal synchronized with the deflection of the electron beam by the deflection coil 108 is supplied.

Moreover, the SEM in FIG. 1 is equipped with a negative-voltage application unit (not illustrated) for applying a negative voltage (which, hereinafter, will be referred to as “retarding voltage” in some cases) to the sample (or a sample holder or sample stage for holding the sample). The application of the retarding voltage reduces the attainment energy (Landing Voltage) of the electron beam which reaches the sample, thereby suppressing a damage of the sample. At the time of the focus, for example, the retarding voltage is used in some cases for the focus adjustment of the electron beam together with or independently of the magnetic-field-type objective lens. Furthermore, based on charge-up information measured by, for example, an charge-up measurement device, the applied voltage can also be controlled so that the charge-up amount will be cancelled.

Also, the SEM illustrated in FIG. 1, which is a critical-dimension scanning electron microscope (Critical-Dimension SEM: CD-SEM), installs therein an algorithm for measuring a pattern dimension on the basis of the line profile acquired based on the electron-beam scanning.

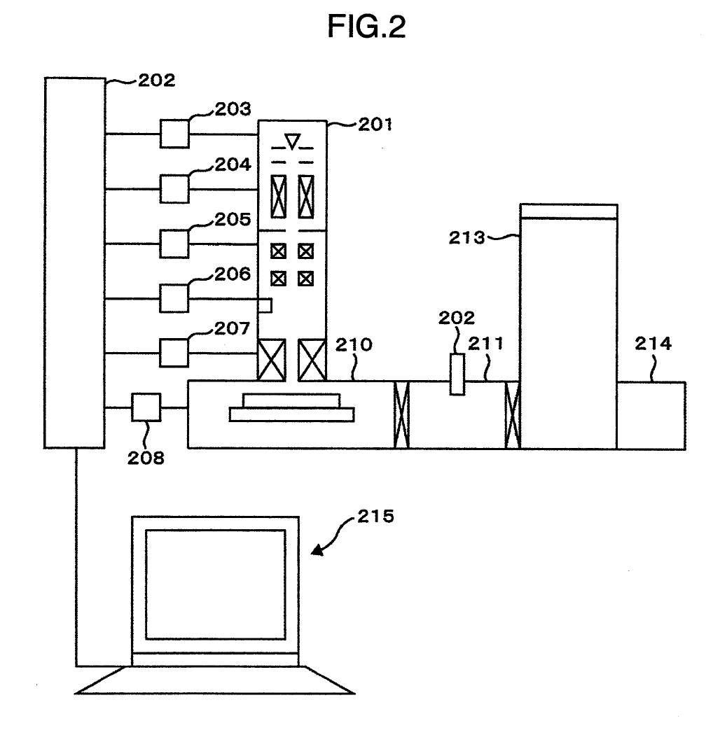

FIG. 2 is a diagram for explaining an embodiment of a control device connected to the SEM. This control device is connected to the SEM as illustrated in FIG. 1 via a not-illustrated communications medium. More concretely, the following components are connected to the main body 201 of the SEM: a signal-detection-system control unit 203, a blanking control unit 204, a beam-deflection correction unit 205, an electron-optics-system correction unit 206, a height detection system 207, and a stage control unit 208, all of which are connected to the entire control unit 202 for issuing commands to the respective control units on the basis of instruction contents registered into a recipe, which will be described later. Also, an auxiliary exhaust chamber 211 is further connected to the SEM's main body 201 via a vacuum valve. This auxiliary exhaust chamber 211 performs an auxiliary exhaust of the sample atmosphere before the sample is introduced into a vacuum chamber 210 of the SEM. Furthermore, a potentiometer 212 for measuring the electric potential of the sample surface which passes through the auxiliary exhaust chamber 211 is provided in the auxiliary exhaust chamber 211. Also, a mini environment 213 is further connected to the auxiliary exhaust chamber 211 via a vacuum valve. A not-illustrated optical microscope and a sample-position adjustment mechanism for performing a global alignment using the optical microscope are built in the mini environment 213. In addition, a load port 214 for dispoing a wafer-(or mask)-built-in cassette is set up with the mini environment 213. Also, although not illustrated, a transfer robot for transferring the sample from the load port 214 to the vacuum chamber 210 is also built in the mini environment 213.

Finally, the configuration components connected to the SEM other than the SEM's main body 201 are also so configured as to perform predetermined operations in accordance with instructions issued from the above-described entire control unit 202 and the state of each configuration component or a detection signal therefor is transmitted to the entire control unit 202.

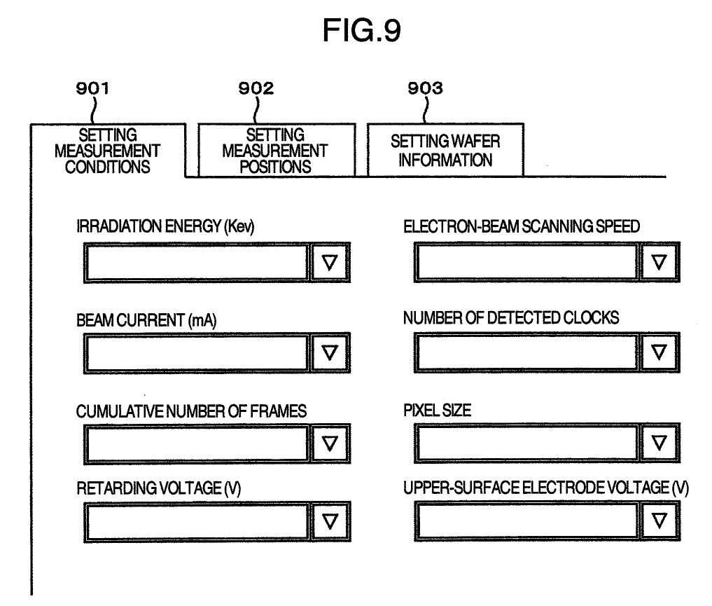

FIG. 9 is a diagram for explaining an embodiment of a recipe-setting screen for creating a recipe for automatically controlling the SEM exemplified in FIG. 1 and FIG. 2. In the present embodiment, the explanation will be given below concerning an example where the recipe is set by a computer 215 in FIG. 2, but not limited thereto. For example, the recipe may also be set by an external computer. A program for setting the recipe is memorized into the computer. The computer 215 is equipped with a recipe-diagnosing function which will be explained hereinafter. This recipe-diagnosing function includes a program for allowing the transition of information associated with pattern matching and autofocus that are set by the recipe which will be explained hereinafter to be displayed on the display device. This information is displayed on, for example, a display set equipped with the computer 215.

FIG. 9 is the embodiment of the screen for setting measurement conditions of the CD-SEM. The display screen explains an example where a window 901 for setting the irradiation conditions for the electron beam is opened. Items for determining the sample imaging conditions, such as electron-beam irradiation energy, beam current, cumulative number of frames, and scanning speed are displayed and the setting of these items allows determination of the imaging conditions for each measurement point with the SEM. In addition, it is so configured as to open a window 902 for setting measurement positions and a window 903 for setting wafer information by selection. Incidentally, the recipe-setting screen in FIG. 9 is merely a partial illustration of the setting screen and it is possible that all of the conditions for the SEM and the SEM-related configuration components be employed as objects to be set and be caused to be displayed as the display items of the recipe-setting screen.

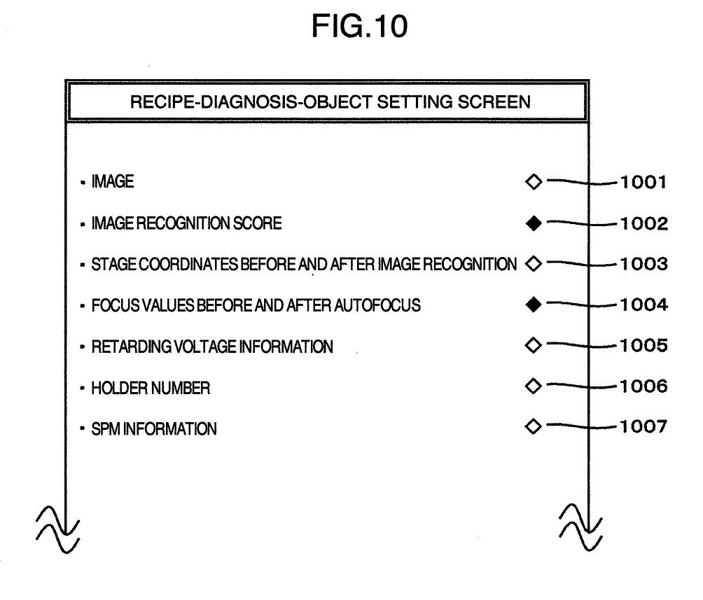

FIG. 10 is a diagram for explaining an embodiment of a selection screen for selecting the operation history of the device acquired in the CD-SEM. On this selection screen, the following selection buttons are provided as an example of selection objects of the operation history: a selection button 1001 for selecting “image”, a selection button 1002 for selecting “image recognition score”, a selection button 1003 for selecting “stage coordinates before and after image recognition”, a selection button 1004 for selecting “focus values before and after autofocus”, a selection button 1005 for selecting “retarding voltage information”, a selection button 1006 for selecting “holder number” of the sample holders for holding the samples, and a selection button 1007 for selecting information of an electrostatic potentiometer (Surface Potential Measurement: SPM), which is one type of potentiometer.

As will be explained later, the above-described selected items are used for making the recipe diagnosis. For example, selecting “image” makes it possible to read out a plurality of images which are acquired by the electron-beam scanning and taking a look at their history makes it possible to visually check the process variation of the semiconductor fabrication process and the like. If, for example, a state can be confirmed where the pattern shape changes gradually despite the same fabrication condition, it can be judged that the semiconductor fabrication process varies in a time-elapsed manner.

Also, by selecting “image recognition score” information on the past image recognition score is read out and displayed in accordance with a predetermined display format. The image recognition score is the score representation of the degree of agreement between the images of the template registered onto the recipe in advance and pattern whose position is identified by a pattern matching processing based on this template. The higher image recognition score means the higher degree of agreement between the template and the pattern formed on the real image.

In other words, the image recognition score is the degree of resemblance between the template image used in image recognition registered when the recipe is created and the object pattern of measurement (or addressing pattern used in position alignment). Namely, it is an evaluation value for whether or not the image-recognition template is appropriate. For example, when the score is high, it indicates that the template image and the object pattern image resemble each other closely. Conversely, when the score is low, it means that a deviation is significant between the template image and the object image and it indicates that some problem or other exists in the template image or the object image.

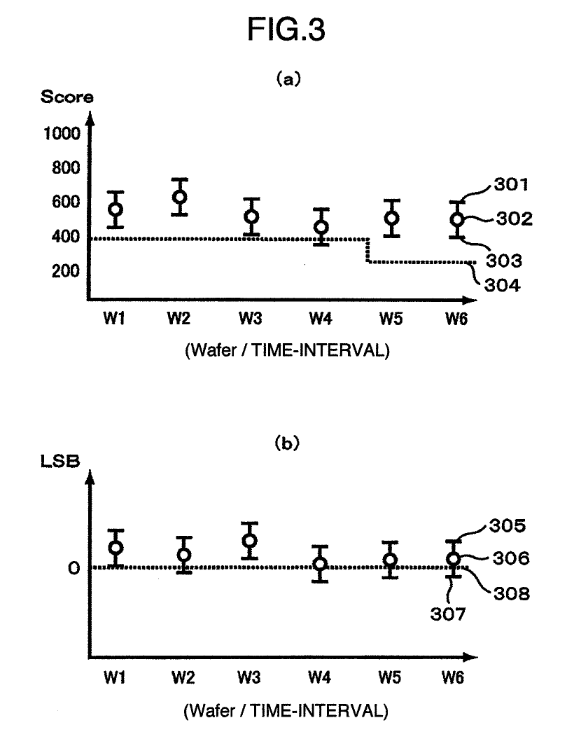

FIG. 3 (a) illustrates an embodiment of the display mode for visually checking the past history of the image recognition score. The graph in FIG. 3 (a), in which the abscissa denotes the wafer (sample) number and the ordinate denotes the image recognition score, represents the transition of the score for each sample unit. In the case of the display embodiment in FIG. 3 (a), W1 to W6 are arranged in a time sequence of each fabrication timing. Incidentally, in the present embodiment, the statistical value (average value) of the score is displayed for each sample unit, but not limited thereto, and may also be arranged in a time sequence for each sample fabrication-day (or fabrication-time) unit, for each predetermined fabrication-lot unit, or for each predetermined fabrication-time-range unit. Also, by displaying a plurality of degree of agreements in statistical values for each predetermined unit, it becomes possible to grasp a tendency of the process variation independently of a variation in the degree of agreements based on another factor such as noise intrusion.

Incidentally, the graph illustrated in FIG. 3 (a) indicates a maximum value 301, an average value 302, and a minimum value 303 of the score. The implementation of a display like this makes it possible to check the deviation in the score of the image recognition template and further makes it possible to judge whether or not the template image is appropriate for the real image which changes due to the process variation and the like.

The process variation does not necessarily occur tremendously in a sudden manner; rather, there is even a case where it changes mildly. If, in a case like this, the same recipe continues to be used without change of the process variation being noticed, a significant deviation arises between the image recognition template and the real image in some cases. Then, the success ratio of the template-based image recognition decreases and it turns out that an unexpected downtime is brought into the CD-SEM.

The transition of the image recognition score in the predetermined unit (such as the sample unit, fabrication-time unit, or fabrication-lot unit) is displayed in order that a judgment on the recipe correction can be made before the occurrence of a downtime as described above. The implementation of a display like this allows the transition of the process variation to be managed using quantitative values. Then, it becomes possible to execute the correction of the recipe or its feedback to the fabrication process with appropriate timing.

Incidentally, in the present embodiment, it is made possible to set and display a tolerable level 304 in advance and to visually make a comparison between the state of the image recognition score and the tolerable level. Here, the nearer the score comes to the tolerable level 504, the higher a possibility becomes that a matching error will occur. Accordingly, the recipe creator finds it possible to consider timing for the recipe update on the basis of the grasp of the transition.

Also, in a case where the real pattern gradually changes due to some circumstances or other, it becomes possible to execute an automatic update of the template image on the basis of the following steps. It is conceivable, for example, to register a program into a partial area of the recipe in advance in which the pattern image on the real image identified by the image recognition template is registered as a new template in a case (A) where the score becomes lower than a predetermined threshold value (or in a case where there arises a difference from the average value of the past scores which is larger than a predetermined value) and in a case (B) where the present score falls within a predetermined difference as compared with the average of the scores over a predetermined number of samples in the past (for example, three wafers) when counted from the present sample.

The above-described case (A) is intended for judging whether or not the degree of agreement between the template and the pattern on the real image becomes lower than the predetermined threshold value while the case (B) is intended for preventing the update of the template from being unnecessarily performed due to a decrease in the degree of agreement which occurs only one time. Providing an algorithm like this allows implementation of the automatic update of the template which is in accordance with the process variation. Also, in substitution for the graph-figured display format as is illustrated in FIG. 3 (a), the transition may also be displayed as a table display format. Whatever type of display format is allowable, as long as it permits the recipe creator to recognize a trend of the change in the degree of agreement. This is also true of the following embodiments.

Also, by selecting “stage coordinates before and after image recognition” a difference (i.e., shift information) between the position identified by the template-based image recognition and an on-sample position which is located below the optical axis of the electron beam by moving a stage based on the coordinate information prior to the image recognition is read out and is displayed in accordance with a predetermined display format. The larger this difference becomes, the higher a possibility becomes that the template-based image recognition will fail. Accordingly, if this transition is grasped and a feedback can be given to the coordinate information registered into the recipe, it becomes possible to prevent a decrease in the throughout beforehand.

Moreover, by selecting “focus values before and after autofocus” deviation information about the objective-lens value (i.e., the current value in the case of a magnetic-field-type objective lens, whereas the voltage value in the case of an electrostatic-type objective lens) at the time when the autofocus is executed at the measurement position (or addressing pattern position) is read out and displayed in accordance with a predetermined display format. This deviation amount's being large means that an adjustment range of the objective lens is large for detecting a just-focus position at the time when the autofocus is executed and that, accordingly, the throughout decreases. Usually, the just-focus position varies due to the height of the sample or the presence of the charge-up. Accordingly, if an objective-lens value at which the autofocus is to be started deviates from the just-focus position which varies in response to the height of the sample or the charge-up amount, it become necessary to search for the just-focus position by enlarging the adjustment range. Consequently, narrowing the difference between the autofocus-starting point and the just-focus position allows implementation of an enhancement in the throughout.

In the present embodiment, it is made possible to display the deviation amount of the objective-lens value ranging from the autofocus-starting point to the just-focus position in the predetermined unit (such as the sample (wafer) unit, fabrication-time unit, or fabrication-lot unit). FIG. 3 (b) illustrates an embodiment of the graph for indicating the transition of the deviation in the objective-lens value at the time when the autofocus is executed. In the graph illustrated in FIG. 3 (b), the abscissa denotes the wafer sample number and the ordinate denotes the objective-lens value (in the present embodiment, DAC value using the LSB as unit). Similar to the embodiment exemplified in FIG. 3 (a), it indicates a maximum value 305, an average value 306, a minimum value 307, and a tolerable level 308.

The implementation of a display like this makes it easier to identify the cause for the delay in the autofocus. As a consequence, it becomes possible to judge timing for the recipe update.

For example, when the LSB value remains entirely high regardless of the sample number, it is conceivable that a problem exists in such a factor as the setting of the recipe (for example, an initial value of the LSB before the autofocus). Also, when the maximum value of the LSB is high although the average value of the LSB on each sample basis is low, it is conceivable that the charge-up or the like adheres onto the wafer locally and that the autofocus time is delayed thereby locally. In a situation like this, the average value itself is low and, consequently, it can be judged that a significant influence will not be exerted onto the throughout decrease.

As having been explained so far, it becomes possible to swiftly identify the factor for the decrease in the focus time. As a consequence, it becomes possible to judge a necessity and timing for the recipe update in correspondence with the usage situation of the device by the user.

Furthermore, when “retarding voltage information” or “SPM information” is selected, the retarding-voltage adjustment width, the retarding-voltage value, the measurement value of SPM, and a difference between a predetermined reference value and the measurement value of SPM for each predetermined unit described earlier are displayed in the display format as was exemplified in FIG. 3. Here, the retarding voltage can also be applied so that the charge-up adhering onto the sample will be cancelled. In a case like this, it becomes possible to monitor the transition of the charge-up on the sample by making displayable the transition of the retarding-voltage value and that of the retarding-voltage adjustment width. If, for example, the average value of the charge-up amount on the sample is found to be rising gradually, it becomes possible to monitor that a situation, which generates the charge-up on the sample, occurs or is occurring in the semiconductor process. This is also similar to the case of the SPM information. By displaying the transition of the SPM-based potential measurement information in sample unit, fabrication-time unit, fabrication-lot unit, or the like, it becomes possible to visually judge in which of the units the process variation is occurring. Also, by making the above-described display switchable for each predetermined unit, it becomes possible to swiftly identify in which of the units the process variation is occurring.

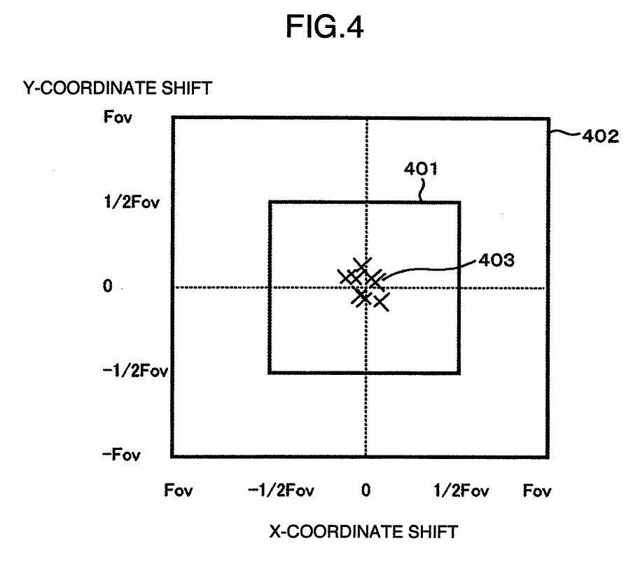

Also, when “stage coordinates before and after image recognition” is selected, it is also allowable to display the shift information as is illustrated in FIG. 4. FIG. 4 is a diagram for explaining an embodiment of displaying, on the image, a FOV area 401 for indicating the field-of-view (FOV) of the SEM, and a FOV-surrounding area 402 for indicating an area which is twice as wide as the FOV.

Like the shift information 403, by displaying a distribution of the shift information about a critical-dimension measurement target for each predetermined unit, it becomes possible to judge whether or not, for example, the magnification of an image used for the image recognition and image-acquiring coordinates used for the image recognition are appropriate.

As having been explained so far, the trends of the respective plural pieces of information, which are selected by the selection on the selection screen in FIG. 10, are displayed and it becomes possible to easily implement the diagnosis of a variation in the semiconductor process and the recipe which should be updated in accompaniment with this variation.

Incidentally, the diagnosis of the recipe is basically classified into the diagnosis of a recipe portion (diagnosis object 1) to which a global alignment condition using an optical microscope is set, the diagnosis of a recipe portion (diagnosis object 2) to which the global alignment condition using the SEM is set, the diagnosis of a recipe portion (diagnosis object 3) to which an addressing condition using the SEM is set, and the diagnosis of a recipe portion (diagnosis object 4) to which a measurement condition in the critical-dimension measurement object is set.

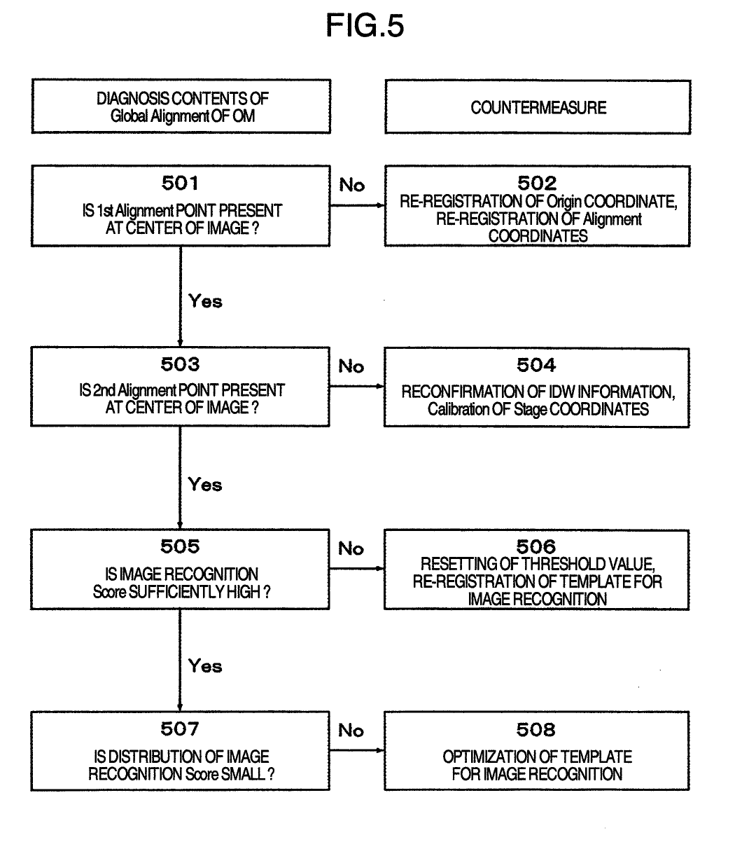

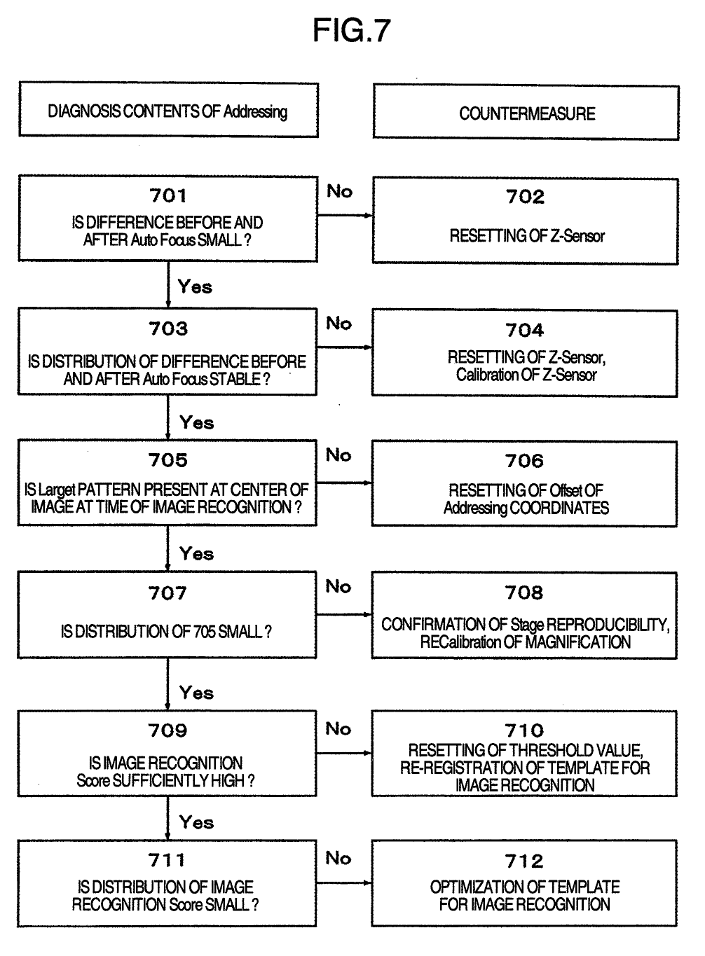

FIG. 5 is a flowchart for explaining a flow of the diagnosis process of diagnosing the above-described diagnosis object 1. In the flowchart illustrated in FIG. 7, a countermeasure is explained which is taken when concrete diagnosis contents are judged along alignment steps and it is judged that a problem exists in each judgment item. Here, the diagnosis in the flow may be automatically executed or may be manually executed after checking the display in FIG. 3 or the like. In the case of executing the diagnosis automatically, for example, at Step 501, it is preferable to provide a function of measuring a shift of a 1st alignment point from the center of the image and a function of comparing this measurement result with a predetermined threshold value. With these functions it is selected whether a countermeasure against the 1st alignment point should be taken (Step 502) or the flow proceeds to a step of searching for the existence of other problem factors (Step 503 or thereinafter). Incidentally, at Step 502, it may be executed to merely issue an error message for notifying the operator of a necessity for the countermeasure. Otherwise, it may be executed to automate the re-registration itself of the coordinates or the like. In the case of automating, it is conceivable that the average value of the shift amount is determined from a distribution of the shift amount as is illustrated in FIG. 4, the determined average value of the shift amount is added to the original coordinates, and then the resultant information is re-registered.

Next, similar processing as the one at Step 501 is executed with respect to a 2nd alignment point as well (Step 503) and it is judged whether a countermeasure against the 2nd alignment point should be taken (Step 504) or there exists another factor. At Step 504, as is the case with the processing at Step 502, the countermeasure can be taken manually or automatically.

Furthermore, at Step 505, it is judged whether or not the image recognition score in the pattern matching is sufficiently high through a comparison with a predetermined threshold value and it is judged whether the flow proceeds to Step 506, which is a countermeasure step, or Step 707, which is a further cause-searching step. When it is judged that a problem exists at Step 507, the flow proceeds to Step 508 which is a countermeasure step thereagainst. When it is judged that no problem exists, the diagnosis of the diagnosis object 1 is terminated.

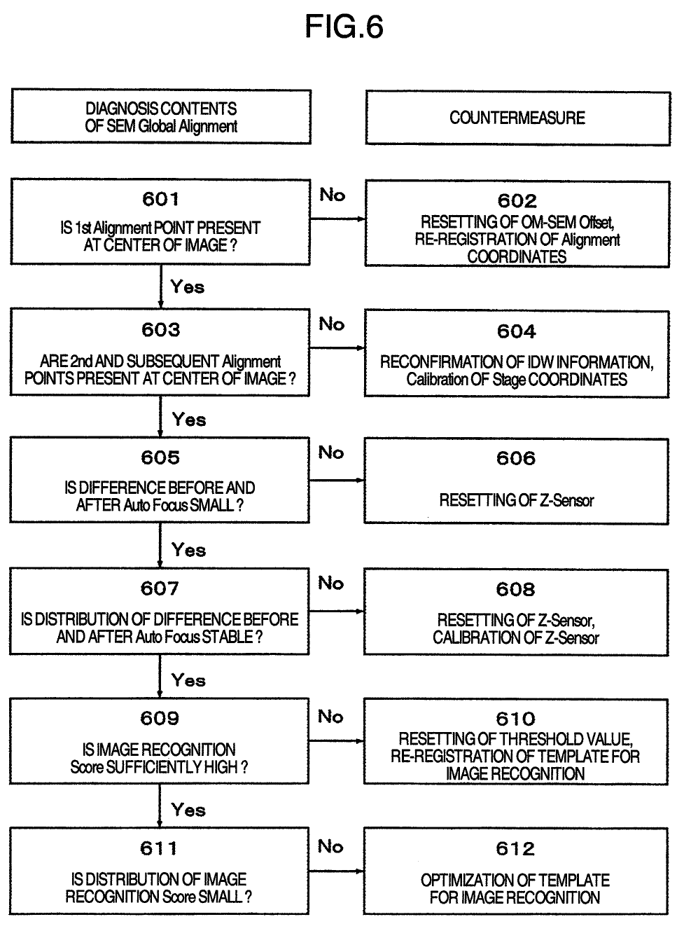

FIG. 6 is a flowchart for explaining a flow of the diagnosis process of diagnosing the above-described diagnosis object 2. Steps 601 and 603 of diagnosis steps and Steps 602 and 604 of countermeasure steps are almost the same as Steps 501 and 503 and Steps 502 and 504 in FIG. 5. At Step 605, depending on whether or not the difference in the lens value before and after the autofocus for an alignment pattern is smaller than a predetermined threshold value, it is judged whether or not the flow proceeds to a countermeasure step 608 or to Step 609, which is a further cause-searching step. At Step 607, it is judged whether or not a variation is present in the difference value in the lens before and after the autofocus through a comparison with a predetermined threshold value.

If, in the global alignment using the SEM, the difference value in the lens is smaller than the predetermined value despite the fact that the alignment pattern appears in the image, there is a possibility that the sample-height measurement result acquired by a Z sensor is inappropriate. Also, if the variation is present in the difference value in the lens before and after the autofocus, similar possibility is conceivable. Accordingly, if, at Steps 605 and 607, it is judged that the countermeasures are necessary, the resetting of the Z sensor or the calibration of the Z sensor is performed.

Incidentally, the Z sensor is a device for measuring the sample height at an electron-beam irradiation position. The Z sensor includes, for example, a light-receiving unit for receiving a laser light which is irradiated from an oblique direction to the electron-beam irradiation position to measure the sample height in correspondence with a light-receiving position of the laser light in the light-receiving unit.

After it is judged at Step 607 that the countermeasures are unnecessary, it is judged whether or not the image recognition score at the time of the alignment is appropriate (Steps 609 and 611). Then, if it is judged that countermeasures are necessary, the flow proceeds to Steps 610 and 612 whereas, if it is judged that no problem exists, the diagnosis of the diagnosis object 2 is terminated.

FIG. 7 is a flowchart for explaining a flow of the diagnosis process of diagnosing the above-described diagnosis object 3. This flowchart is one for judging whether or not the device-setting conditions for an addressing pattern for identifying the critical-dimension measurement location with the CD-SEM is appropriate. The addressing pattern is common with the global alignment pattern in the point that the template-based matching for the image recognition is executed and the flowchart for diagnosis includes the portion which is common to the one illustrated in FIG. 6. The addressing pattern, however, is in a relationship of already-known position with the critical-dimension measurement object pattern; it is used for deflecting (i.e., image-shifting) the electron beam based on the recognition of the addressing pattern to the critical-dimension measurement object pattern which is in the already-known position relationship with the addressing pattern. Also, it is desirable that, in order to enhance the measurement accuracy, the measurement object pattern be positioned directly below the optical axis of the electron beam. Consequently, at Step 705, it is judged whether or not the critical-dimension measurement object pattern is present at the center of the image (FOV); if it is not present at the center of the image (for example, if the critical-dimension measurement object pattern shifts by an amount of a predetermined value or more from the center position), the resetting of offset of the addressing pattern coordinates is executed (Step 706).

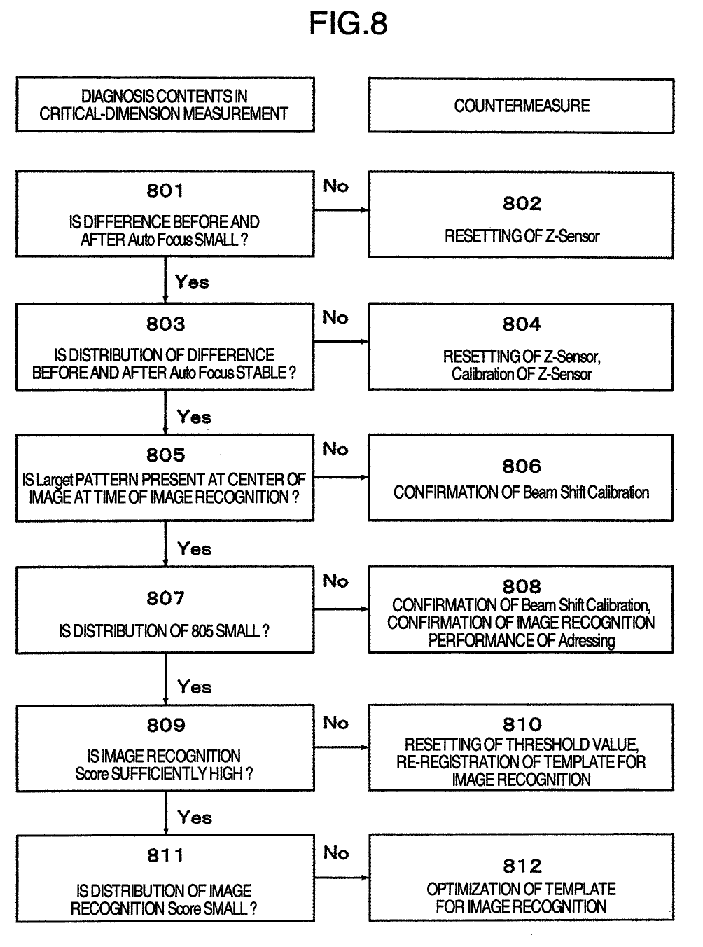

FIG. 8 is a flowchart for explaining a flow of the diagnosis process of diagnosing the above-described diagnosis object 4. In the present embodiment, since the position identification of the measurement object pattern is executed using the template for the image recognition as is the case with the addressing pattern or the like, the recipe diagnosis based on a similar sequence to the one of the addressing pattern or the like is possible.

As having been explained so far, by executing the recipe diagnosis for each diagnosis item of the above-described diagnosis objects based on the information acquired at the time of the recipe execution, it becomes possible to judge the appropriateness of the individual recipe-setting items, thereby allowing implementation of the countermeasures which are capable of addressing each diagnosis item further.

### REFERENCE SIGNS LIST

101 cathode
102 first anode
103 second anode
104 electron beam
105 condenser lens
106 objective lens
107 wafer
108 deflection coil
109 deflector control power-supply
110 secondary electrons
111 electron detector
112 amplifier
113 display device
114 lens control power-supply

1. A recipe diagnosis device of diagnosing a recipe used for operating a scanning electron microscope,
said recipe diagnosis device, comprising:
a program for allowing transition of information to be displayed on a display device, said information being about setting items of said recipe.

2. The recipe diagnosis device according to claim 1, wherein
said setting items of said recipe are information about pattern matching and autofocus,
said pattern matching being used for identifying a desired position on said scanning electron microscope, said autofocus being used for automatically adjusting focal point of a lens of said scanning electron microscope.

3. The recipe diagnosis device according to claim 2, wherein
said information about said pattern matching is information about a score for indicating degree of agreement of said pattern matching.

4. The recipe diagnosis device according to claim 2, wherein
said information about said autofocus is information about lens values before and after said autofocus.

5. The recipe diagnosis device according to claim 1, wherein
said transition of said information about said setting items of said recipe is transition of statistical values of said information in a predetermined unit.

6. The recipe diagnosis device according to claim 5, wherein
said statistical values in said predetermined unit is said transition of said statistical values in sample unit, sample fabrication-day unit, sample fabrication-time unit, predetermined fabrication-lot unit, or predetermined fabrication-time-range unit.
